(19) United States
(12) Patent Application Publication
(10) Pub. No.: US 2026/0227709 A1
(43) Pub. Date: Aug. 6, 2026

(54) MEASUREMENT DEVICE, METHOD OF MEASUREMENT, AND METHOD OF MANUFACTURING DEVICES

(71) Applicant: ASML NETHERLANDS B.V., Veldhoven (NL)

(72) Inventors: Ruud Hendrikus Martinus Johannes BLOKS, Helmond (NL); Arend Johannes DONKERBROEK, Aarle-Rixtel (NL); Max Leonardus Petrus DE LANGE, Roermond (NL)

(73) Assignee: ASML NETHERLANDS B.V., Veldhoven (NL)

(21) Appl. No.: 19/153,279

(22) PCT Filed: Jan. 9, 2024
(86) PCT No.: PCT/EP2024/050410

§ 371 Date: Aug. 1, 2025

(30) Foreign Application Priority Data
Feb. 9, 2023 (EP) 23155897.4

(51) Int. Cl. G03F 7/00; G03F 9/00

(52) U.S. Cl. CPC G03F 7/706849; G03F 7/706851; G03F 9/7088

(57) ABSTRACT

A measurement device for measuring a substrate, the measurement device including: an optical sensor configured to make a measurement of a substrate surface by emitting a radiation beam; and a fluid supply configured to supply a conditioning fluid traversing the beam and flowing in a slit between the measurement device and the substrate surface, wherein the optical sensor is configured to perform a first measurement process while the measurement device is moving relative to the substrate at a first speed, and to perform a second measurement process while the measurement device is moving relative to the substrate at a second speed higher than the first speed, and wherein the fluid supply is configured to supply the conditioning fluid at a first flow rate during the first measurement process, and to supply the conditioning fluid at a second flow rate higher than the first flow rate during the second measurement process.

### CROSS-REFERENCE TO RELATED APPLICATIONS

This application claims priority of EP Application Serial No. 23155897.4 which was filed on 9 Feb. 2023 and which is incorporated herein in its entirety by reference.

### FIELD

The present invention relates to a measurement device for measuring a substrate in a lithographic apparatus, a method of measurement, and a method of manufacturing devices.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

In view of the increasingly demanding level of precision of manufacturing devices, it has been increasingly important to obtain precise measurements of the substrate. These measurements include horizontal alignment, which may be achieved by using an alignment sensor to detect a marker on the surface of the substrate, and level sensing, which may be achieved by using a level sensor to measure the topography of the surface of the substrate. Typically, these sensors may be optical sensors. Once these measurements are made, the lithographic apparatus may be calibrated accordingly, so as to compensate for any misalignment and non-planarity of the substrate during manufacturing.

In the context of the degree of precision required, it has been known that the measurement precision can be degraded by a poor control of the fluid (e.g. air) conditions in the optical paths of the sensors. These conditions may include the composition of the fluid, temperature, at the like. As such, attempts have been made to control the fluid conditions by supplying a flow of conditioning fluid to the optical paths. The conditioning fluid can be controlled to have known and stable conditions. This way, the optical paths may be free of perturbations by external fluids, such as the ambient fluid surrounding the measurement device.

However, known attempts of controlling the fluid conditions do not provide perfectly stable conditions. This places a limit on the degree of precision achievable by the sensors, as well as on the speed at which the whole substrate can be measured. This, in turn, limits the smallest features achievable by lithography, increases scrap rate, and limits production speed.

### SUMMARY

An aim of the present invention is thus to increase the level of precision achievable by lithography.

Another aim of the present invention is to reduce scrap rate in the manufacture of devices using lithography.

Yet another aim of the present invention is to increase the production speed of lithography.

According to an aspect of the present invention, there is provided a measurement device for measuring a substrate in a lithographic apparatus, the measurement device comprising:
an optical sensor configured to make a measurement of a surface of the substrate by emitting a light beam; and
a fluid supply configured to supply a conditioning fluid traversing the light beam and flowing in a slit between the measurement device and the surface of the substrate;
wherein the optical sensor is configured to perform a first measurement process while the measurement device is moving relative to the substrate at a first speed, and to perform a second measurement process while the measurement device is moving relative to the substrate at a second speed higher than the first speed;
wherein the fluid supply is configured to supply the conditioning fluid at a first flow rate during the first measurement process, and to supply the conditioning fluid at a second flow rate higher than the first flow rate during the second measurement process.

According to another aspect of the present invention, there is provided a method of measuring a substrate in a lithographic apparatus using a measurement device, the method comprising:
emitting a light beam onto a surface of the substrate; and
supplying a conditioning fluid traversing the light beam and flowing in a slit adjacent the surface of the substrate;
during a first measurement process, moving the substrate relative to the light beam at a first speed supplying the conditioning fluid at a first flow rate; and
during a second measurement process, moving the substrate relative to the light beam at a second speed higher than the first speed while supplying the conditioning fluid at a second flow rate higher than the first flow rate.

### BRIEF DESCRIPTION OF THE DRAWINGS

Embodiments of the invention will now be described, by way of example only, with reference to the accompanying schematic drawings, in which:

FIG. 1 schematically depicts a lithographic apparatus according to an embodiment of the invention;

FIG. 2 schematically depicts a cross-section of a measuring device shown in FIG. 1;

FIGS. 3a-3d schematically depict various flow profiles of a conditioning fluid;

FIG. 4 schematically depicts a control volume in three-dimensional view;

FIG. 5 schematically depicts the control volume in plan view;

FIG. 6 schematically depicts level sensing of the substrate; and

FIG. 7 schematically depicts horizontal alignment of the substrate.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

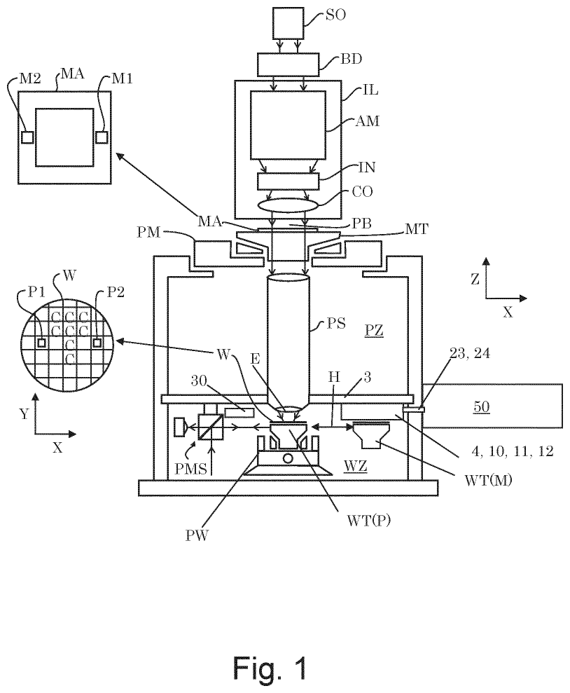

FIG. 1 schematically depicts a lithographic apparatus according to one embodiment of the invention. The apparatus comprises: an illumination system (illuminator) IL configured to condition a radiation beam PB (e.g., UV radiation, DUV radiation or EUV radiation); a mask support (e.g. a mask table) MT constructed to support a patterning device (e.g. a mask) MA and connected to a first positioner PM configured to accurately position the patterning device MA in accordance with certain parameters; a substrate support (e.g. a substrate table) WT constructed to hold a substrate (e.g. a resist-coated wafer) W and connected to a second positioner PW configured to accurately position the substrate W in accordance with certain parameters; and a projection system (e.g. a refractive projection lens system) PS configured to project a pattern imparted to the radiation beam PB by patterning device MA onto a target portion C (e.g. comprising one or more dies) of the substrate W.

In operation, the illumination system IL receives a radiation beam PB from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam PB to have a desired spatial and angular intensity distribution in its cross section at a plane of the patterning device MA.

The term “projection system” used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system”.

The lithographic apparatus may be of a type wherein at least a portion of the substrate W may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not shown). The measurement stage is arranged to hold a sensor and/or a cleaning device. The sensor may be arranged to measure a property of the projection system PS or a property of the radiation beam PB. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam PB is incident on the patterning device MA, e.g. mask, which is held on the mask support MT, and is patterned by the pattern (design layout) present on patterning device MA. Having traversed the patterning device MA, the radiation beam PB passes through the projection system PS, which focuses the radiation beam PB onto a target portion C of the substrate W. With the aid of the second positioner PW and a position measurement system PMS, the substrate support WT can be moved accurately, e.g., so as to position different target portions C in the path of the radiation beam PB at a focused and aligned position. Similarly, the first positioner PM and possibly another position sensor (which is not explicitly depicted in FIG. 1) may be used to accurately position the patterning device MA with respect to the path of the radiation beam PB. Patterning device MA and substrate W may be aligned using mask alignment marks M1, M2 and substrate alignment marks P1, P2. Although the substrate alignment marks P1, P2 as illustrated occupy dedicated target portions C, they may be located in spaces between target portions C. Substrate alignment marks P1, P2 are known as scribe-lane alignment marks when these are located between the target portions C. Suitable techniques are described in more detail in US2009/195768A, which is incorporated by reference.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

In an embodiment, shown in FIG. 1, the substrate support WT is moveable, to transfer the substrate W, held by the substrate support WT, at least from a substrate measuring position to a substrate processing position. In FIG. 1, a substrate support position to hold the substrate W in the processing position is indicated by WT(P), i.e., a substrate processing position. A substrate support position to hold the substrate W in the measuring position is indicated by WT(M), i.e., a substrate measuring position. As an example, the substrate measuring position WT(M) can be located away from a downstream end E of the projection system PS, whereas the substrate processing position WT(P) can be located near and/or opposite that downstream end E of the projection system PS.

When the substrate support WT holds the substrate W in the processing position, i.e., substrate processing position WT(P), the substrate W can be illuminated by the projection system PS. Particularly, the substrate W cannot be exposed by the projection system PS when the substrate W is in the substrate measuring position WT(M). Preferably, during the moving of the substrate support WT from a respective substrate measuring zone, e.g., substrate measuring position WT(M) to a respective substrate projection zone, e.g., substrate processing position WT(P), the substrate W remains in the same position on the substrate support WT.

For example, the substrate measuring position WT(M) and the substrate processing position WT(P) can be located in the same interior part or chamber of the apparatus, for example, in a substrate zone WZ of the apparatus. As an example, an intermediate frame part 3 (for example a metrology frame part) of the apparatus can substantially separate this interior substrate zone WZ from one or more other apparatus zones, such as from a projection system zone PZ. Alternatively, the substrate measuring position WT(M) and the substrate processing position WT(P) can be located in different zones, for example in case the substrate measuring position WT(M) is located outside the apparatus.

The movement of the substrate support WT between desired substrate measure position WT(M) and substrate processing position WT(P) can be carried out by various means, as will be clear to the skilled person. For example, at least part of such a movement can be provided with the aid of the second positioner PW, a substrate support conveyor and/or by one or more other transport mechanisms. In a further embodiment, the substrate support WT is movable from the substrate measuring position WT(M) to the substrate processing position WT(P) substantially in a single virtual plane or level. As a non-limiting example, in FIG. 1, the substrate support WT can be movable in a substantially horizontal direction H, or the XY-plane, to move the substrate W in a substantially horizontal direction or along the XY-plane from the substrate measuring position WT(M) to the substrate processing position WT(P), or vice versa.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the projection system PS or the intermediate frame part 3, e.g., a metrology frame. The position measurement system PMS may determine the position of the substrate support WT and/or the mask support MT by measuring the position or by measuring a time derivative of the position, such as velocity or acceleration.

The position measurement system PMS may comprise an encoder system (not shown). An encoder system is known from for example, US2007058173A1, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1st order, −1st order, +2nd order and −2nd order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate support WT. The other of the encoder head and the grating may be arranged on the intermediate frame part 3, e.g., a metrology frame or a base frame. For example, a plurality of encoder heads are arranged on the metrology frame, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system (not shown). An interferometer system is known from, for example, U.S. Pat. No. 6,020,964, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame. In an embodiment, the measurement beam and the reference beam are combined into a combined radiation beam by an additional optical component instead of the beam splitter.

The lithography apparatus comprises a measurement device comprising an optical sensor 10, 11, 12 configured to or capable of measuring at least one aspect and/or characteristic of the substrate W when the substrate support WT holds the substrate W in the substrate measuring position WT(M). Such a measuring device, which has been schematically depicted in the Figures, can be constructed in various ways. In a further embodiment, the measuring device can be configured to use one or more measuring beams to measure or monitor the substrate W. For example, in a further embodiment, the optical sensor 10, 11, 12 can be capable of directing or emitting one or more measuring light beams towards the surface of the substrate W. For example, in that case, the measuring device can also be configured to detect at one or more parts of the measuring light beam(s) which are reflected by the substrate surface.

Herein, the term “light beam” should be interpreted broadly. The measuring (light) beam can be a suitable radiation beam, that can be at least partly reflected by the surface of a substrate W to be measured. For example, the measuring beam can include an optical beam of radiation of one or more wavelengths in the visible range, an/or a light beam having one or more different wavelengths of radiation.

For example, the measuring device can be configured to measure a position and/or orientation of the substrate W with respect to the substrate support (or table) WT. Such a position and/or orientation of the substrate W can include a certain alignment or misalignment of the substrate W with respect to the substrate support WT, one or more substrate positions measured in directions parallel to the substrate's surface, a certain tilt of the substrate W, a certain rotational substrate position, a level, thickness and/or of height position of the substrate measured perpendicularly with respect to the substrate surface, and/or other substrate positions and/or orientations. For example, the measuring device can be configured to provide data, which can be used to detect the position of the substrate W with respect to the substrate support WT in 6 different degrees of freedom. Also, the measuring device can be configured to detect the position of the substrate support WT when the substrate support WT holds a substrate W in the substrate measuring position WT(M). Besides, the measuring device can be provided with (predetermined) information concerning a precise position of the substrate support WT, when the substrate support WT holds the substrate W in the substrate measuring position WT(M). The apparatus can comprise control means, which can control the measuring device, and can use measuring results to calculate or estimate certain aspects of the substrate W. Such control means are not depicted; to the skilled person, it will be clear how such control means can be configured.

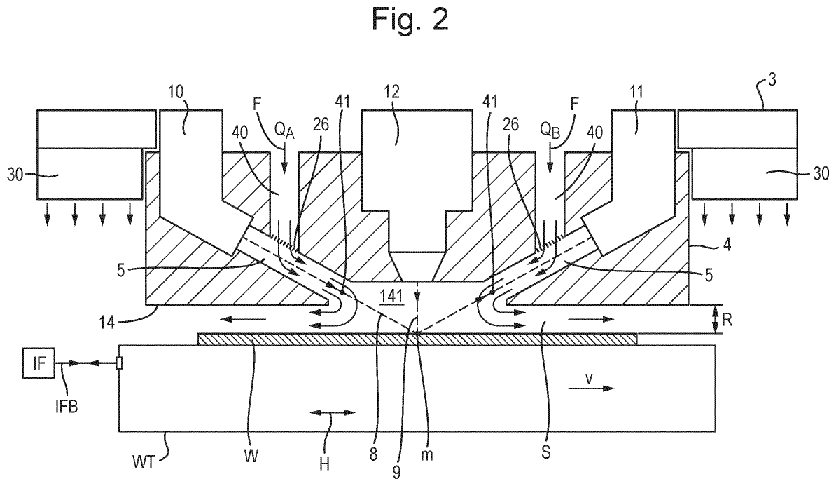

In an embodiment, the measuring device can be provided with one or more optical sensors 12, e.g., alignment sensors to measure the positions of substrate alignment markers P1, P2 which can be provided on a substrate W, for detecting the position of the substrate W in a certain plane (such as the XY plane in FIG. 1). In FIG. 2, an embodiment of an alignment sensor is schematically depicted. The alignment sensor can be configured to emit one or more alignment measuring beams 9 towards the surface of the substrate W, held in the substrate measuring position WT(M), and to detect reflected parts of the alignment measuring beams 9.

Suitable optical (alignment or position) sensors 12 may use optical phenomena such as diffraction and interference to obtain position information from substrate alignment marks P1, P2 formed on the substrate W. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

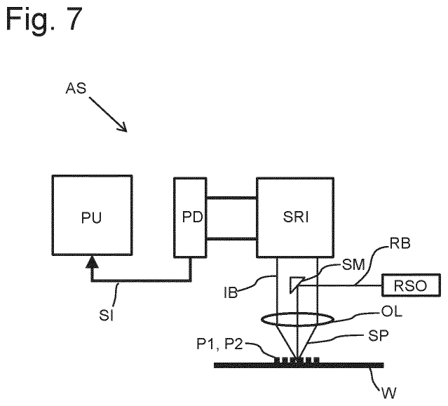

In more detail, FIG. 7 is a schematic block diagram of an embodiment of a known alignment sensor AS, such as is described, for example, in U.S. Pat. No. 6,961,116, and which is incorporated by reference. Radiation source RSO provides a beam RB of radiation of one or more wavelengths, which is diverted by diverting optics onto a mark, such as substrate alignment mark P1, P2 located on substrate W, as an illumination spot SP. In this example the diverting optics comprises a spot mirror SM and an objective lens OL. The illumination spot SP, by which the substrate alignment mark P1, P2 is illuminated, may be slightly smaller in diameter than the width of the substrate alignment mark P1, P2 itself.

Radiation diffracted by the mark AM may be collimated (in this example via the objective lens OL) into an information-carrying beam IB. The term “diffracted” is intended to include zero-order diffraction from the mark (which may be referred to as reflection). A self-referencing interferometer SRI, e.g. of the type disclosed in U.S. Pat. No. 6,961,116 mentioned above, may interfere the information-carrying beam IB with itself after which the information-carrying beam IB is received by a photodetector PD. Additional optics (not shown) may be included to provide separate beams in case more than one wavelength is created by the radiation source RSO. The photodetector PD may be a single element, or it may comprise a number of pixels, if desired. The photodetector PD may comprise a sensor array.

The diverting optics, which in this example comprises the spot mirror SM, may also serve to block zero order radiation reflected from the substrate alignment mark P1, P2, so that the information-carrying beam IB comprises only higher order diffracted radiation from the substrate alignment mark P1, P2 (this is not essential to the measurement, but improves signal to noise ratios).

Intensity signals SI are supplied to a processing unit PU. By a combination of optical processing in the block SRI and computational processing in the unit PU, values for X- and Y-position on the substrate W relative to a reference frame are output.

A single measurement of the type illustrated only fixes the position of the substrate alignment mark P1, P2 within a certain range corresponding to one pitch of the substrate alignment mark P1, P2. Coarser measurement techniques are used in conjunction with this to identify which period of a sine wave is the one containing the marked position. The same process at coarser and/or finer levels may be repeated at different wavelengths for increased accuracy and/or for robust detection of the substrate alignment mark P1, P2 irrespective of the materials from which the substrate alignment mark P1, P2 is made, and materials on and/or below which the substrate alignment mark P1, P2 is provided. The wavelengths may be multiplexed and de-multiplexed optically so as to be processed simultaneously, and/or they may be multiplexed by time division or frequency division.

Alternatively or additionally, the measuring device can be provided with one or more optical sensors 10, 11, i.e., level sensors, configured to detect a certain levelling of a substrate W held in the substrate measuring position WT(M). In the embodiment of FIG. 2, the optical sensors 10, 11, e.g., level sensors comprise a number of level measuring beam emitters, configured to emit a plurality of substantially parallel level measuring beams 8, and one or more level measuring beam detectors to detect reflected parts of the level measuring beams 8. As is shown in FIG. 2, the alignment measuring beam(s) 9 and the level measuring beam(s) 8 can be directed towards substantially the same location m of the substrate surface by the respective optical sensors 10, 11, 12. Alternatively, various measuring beams 8, 9 can be directed towards different substrate parts. Besides, as is shown in FIG. 2, an angle of incidence of a mentioned level measuring beam 8 can be significantly larger (closer to 90°, for example more than 45°, more than 55°, more than 60°, or more than 70°, or up to about) 80° than an angle of incidence of a mentioned alignment measuring beam 9 (the angles of incidence being measured with respect to a normal to the substrate surface).

More specifically, the level sensor may be arranged to measure a topography of a top surface of a substrate (or wafer) W. A map of the topography of the substrate W, also referred to as height map, may be generated from these measurements indicating a height of the substrate W as a function of the position on the substrate W. This height map may subsequently be used to correct the position of the substrate W during transfer of the pattern on the substrate W, in order to provide an aerial image of the patterning device MA in a properly focus position on the substrate W. It will be understood that “height” in this context refers to a dimension broadly out of the plane to the substrate W (also referred to as Z-axis). Typically, the level or height sensor performs measurements at a fixed location (relative to its own optical system) and a relative movement between the substrate W and the measurement device comprising the level sensor results in height measurements at locations across the substrate W.

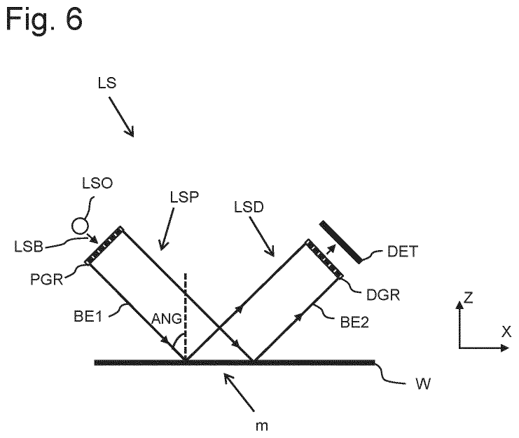

An example of a level or height sensor LS as known in the art is schematically shown in FIG. 6, which illustrates only the principles of operation. In this example, the level sensor LS comprises an optical system, which includes a projection unit LSP serving as optical sensor 10, e.g., level measuring beam emitters, and a detection unit LSD serving as optical sensor 11, e.g., level measuring beam detectors. The projection unit LSP may comprise a radiation source LSO providing a beam of radiation LSB which is imparted by a projection grating PGR of the projection unit LSP. The radiation source LSO may be, for example, a narrowband or broadband radiation source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate W.

The projection grating PGR is a periodic grating comprising a periodic structure resulting in a beam of radiation BE1 having a periodically varying intensity. The beam of radiation BE1 with the periodically varying intensity is directed towards a measurement location m on a substrate W having an angle of incidence ANG with respect to an axis perpendicular (Z-axis) to the incident substrate surface between 0 degrees and 90 degrees, typically between 70 degrees and 80 degrees. At the measurement location m, the patterned beam of radiation BE1 is reflected by the substrate W (indicated by arrows BE2) and directed towards the detection unit LSD.

In order to determine the height level at the measurement location m, the level sensor LS further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as a photodetector, or representative of a spatial distribution of the intensity received, such as a camera. The detector DET may comprise any combination of one or more detector types.

By means of triangulation techniques, the height level at the measurement location m can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas m or spots covering a larger measurement range.

Various height sensors of a general type are disclosed for example in U.S. Pat. Nos. 7,265,364 and 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

The measuring device can also be provided with one or more other sensors, for example with one or more planar encoders (not depicted). Also, in case the measuring device is configured to use one or more measuring fields, the measuring device can comprise one or more suitable field generators, for example one or more electromagnetic field generators in case the measuring field is an electromagnetic field, as will be clear to the skilled person.

The measuring device can provide a remote sensing means, to detect the position and/or orientation of the substrate W prior to the substrate W being illuminated by the projection system PS. Particularly, results of the measurement of the location and/or orientation of the substrate W with respect to the substrate support WT can be used to focus and/or direct a patterned radiation beam PB onto a desired part of the substrate W, to position the substrate support WT with respect to the patterned radiation beam PB, or in a different way. In a further embodiment, the substrate W is not being repositioned with respect to the substrate support WT during a period which runs from the measuring device measuring or detecting the substrate's position/orientation to the projection system PS having projected the radiation beam PB onto the substrate W. In that case, the measurement results of the present measurement system are not used to (re) align the substrate W with respect to the substrate support WT as such.

Alternatively, the measurement results of the measurement system are used to (re) align the substrate W with respect to the substrate support WT, before the patterned radiation beam PB is projected onto the substrate W.

The optical sensor 10, 11, 12 is capable of performing several different measurement processes. Depending on the measurement process, the measurement device may move at different speeds v relative to the substrate W (note that the speed v is to be understood in a relative sense, i.e. either the substrate W or the measurement device may be thought of as “moving” depending on the frame of reference). Specifically, the measurement device moves at a first speed v₁ relative to the substrate W during a first measurement process, and moves at a second speed v₂ relative to the substrate W during a second measurement process.

Different measurement processes may be desirably performed at different speeds v on consideration of a balance between measurement precision and the time it takes to complete the measurement process. That is, in general, provided that adequate precision can be reliably obtained, it may be desirable to perform a measurement process at the highest speed v possible. For example, it may be possible to perform level sensing (e.g. measuring the topography of the surface of the substrate W) at a higher speed v than horizontal alignment (e.g. detecting a substrate alignment marker P1, P2 on the surface of the substrate W).

However, in the context of the degree of measurement precision required, it has been found that the flow of the fluid (whether liquid or gas) through which the light beam 8, 9 passes may generate changes in the refractive index of the fluid to such an extent that measurement precision is substantially degraded. For example, when the measurement device is moving at a high speed v relative to the substrate W, there may be a significant fluid backflow from outside the slit S in towards the vicinity of the location m where the light beam 8, 9 is incident on the surface of the substrate W. At such high speeds v, the fluid flow in the slit S and the vicinity of the location m may even become turbulent. Such backflows and turbulent flows may be unpredictable, and may cause significant changes in the refractive index of the fluid, thereby degrading measurement precision.

Therefore, it may be desirable to provide a passive means or barrier, to prevent ambient fluid to reach the paths of the measuring beams 8, 9, or to reduce the chance that ambient fluid can reach those paths. Therefore, the measurement device is provided with a supply of conditioning fluid F. In an embodiment, the fluid supply may be provided by a conditioning system 50 of the lithography apparatus. The conditioning fluid F may be used to condition at least part of a path of the measuring beams 8, 9 of the measuring device. An embodiment of such a conditioning system is schematically depicted in FIGS. 1 and 2.

As shown in FIG. 2, the measurement device is configured to supply the conditioning fluid F such that it traverses the light beam 8, 9 and flows in a slit S between the measurement device and the surface of the substrate W. More specifically, the measurement device may comprise a space filling and/or space enclosing body 4, having a fluid flow control surface 14. The fluid flow control surface 14 extends opposite the substrate measuring position WT(M) (see FIG. 2). The fluid flow control surface 14 may be arranged to provide or enclose the slit S with at least the substrate surface part of a substrate W held in the substrate measuring position WT(M), which substrate surface part is faced away from the substrate support WT and receives the measuring beams 8, 9 of the measuring device during use. The fluid flow control surface 14 may extend substantially parallel to the substrate surface of the substrate W held in the substrate measuring position WT(M). The fluid flow control surface 14 may extend opposite the whole surface of the substrate W, located in the substrate measuring position WT(M), and optionally opposite at least a surface part of an opposite substrate support WT. In this way, a relatively long, narrow, slit S may be provided between the substrate W surface and the space filling and/or space enclosing body 4.

The fluid flow control surface 14 as such can be arranged and configured in various ways. For example, the fluid flow control surface 14 can be a substantially flat, substantially continuous or uninterrupted surface, except for a aperture 141 through which the conditioning fluid F from the space filling/enclosing body 4 enters the slit S and through which the light beam 8, 9 travels between the optical sensor 10, 11, 12 and the surface of the substrate W. The fluid flow control surface 14 may be interrupted by other features as required. Although the fluid flow control surface 14 may be substantially flat, the fluid flow control surface 14 need not be microscopically smooth and may have small surface features. For example, the fluid flow control surface 14 may be profiled, include small fluid guiding grooves and/or comprise a certain relief, for example to direct fluid along that fluid flow control surface 14 towards a desired direction.

As noted above, the measurement device performs a first measurement process while the measurement device is moving relative to the substrate W at a first speed v₁, and performs a second measurement process while the measurement device is moving relative to the substrate W at a second speed v₂ higher than the first speed. The first measurement process may be an alignment process in which the position of a substrate alignment marker P1, P2 on the substrate W is measured, which may be performed at a speed which is low enough to be considered quasi-static. The second measurement process may be a level sensing process in which the topography of the surface of the substrate W is measured, which may be performed at high speed, e.g. up to about 3.0 m/s or 4.5 m/s.

Accordingly, a simplistic approach to providing a barrier to the ambient fluid flow would be to supply the conditioning fluid F at a sufficiently high flow rate, so that the fluid conditions (e.g. refractive index) in the path of the light beam 8, 9 are predominantly determined by the supply of conditioning fluid F, and perturbations from the ambient fluid can be largely excluded. This may improve the consistency and predictability of the fluid conditions for the different measurement processes, which may be accordingly calibrated.

However, as found by the present inventors, this simplistic approach has a drawback. Although the conditioning fluid F may be supplied at arbitrarily high flow rates so as to maximally exclude or counteract perturbations from the ambient fluid in the slit S, such high flow rates may generate turbulent flow within the space filling/enclosing body 4. For example, as shown in FIG. 2, the conditioning fluid F may be supplied via a fluid passage 40, which may be constricted and/or have bends which are prone to generating turbulence. In particular, a sieve 26 may be provided in the fluid passage 40 to make the flow profile more uniform, but it may also generate turbulence if the flow rate is too high. Certain measurement processes are particularly sensitive to such turbulences. In certain other measurement processes, this kind of turbulences may be tolerable if the required measurement precision can still be achieved.

Therefore, it may be desirable to supply the conditioning fluid F in an adaptive manner. Specifically, the fluid supply is configured to supply the conditioning fluid F at a first flow rate Q₁ during the first measurement process, and to supply the conditioning fluid F at a second flow rate Q₂ higher than the first flow rate during the second measurement process. As such, in the second measurement process, which takes place at a high speed v₂, a high flow rate Q₂ of conditioning fluid F is supplied, so that the fluid conditions in the slit S may be substantially shielded from perturbations by the ambient fluid. In the first measurement process, which takes place at a slow speed v₁, a lower flow rate Q₁ of conditioning fluid F is supplied, so that the generation of turbulence in the fluid passage 40 is limited or altogether avoided.

As noted above, the optical sensor may comprise an optical sensor 12, e.g., alignment sensor configured to detect a marker on the surface of the substrate W for horizontal alignment. Furthermore, this horizontal alignment may need to be performed at a quasi-static speed v in order to obtain the requisite measurement precision. As found by the present inventors, this type of alignment may be particularly sensitive to turbulence generated in the fluid passage 40 (due to the quasi-static speed v, perturbations from the ambient fluid may be small). Therefore, horizontal alignment may be performed as the first measurement process at a slow speed v₁ and low flow rate Q₁ of conditioning fluid F.

As noted above, the optical sensor 10, 11 may comprise a level sensor configured to measure a topography of the surface of the substrate W. This level sensing may be desirably performed at a high speed v (e.g. up to 3.0 to 4.5 m/s) so as to save time. As found by the present inventors, this type of level sensing may be predominantly sensitive to perturbations from the ambient fluid, and less sensitive to turbulences generated within the fluid passage 40. Therefore, level sensing may be performed as the second measurement process at a high speed v₂ and high flow rate Q₂ of conditioning fluid F.

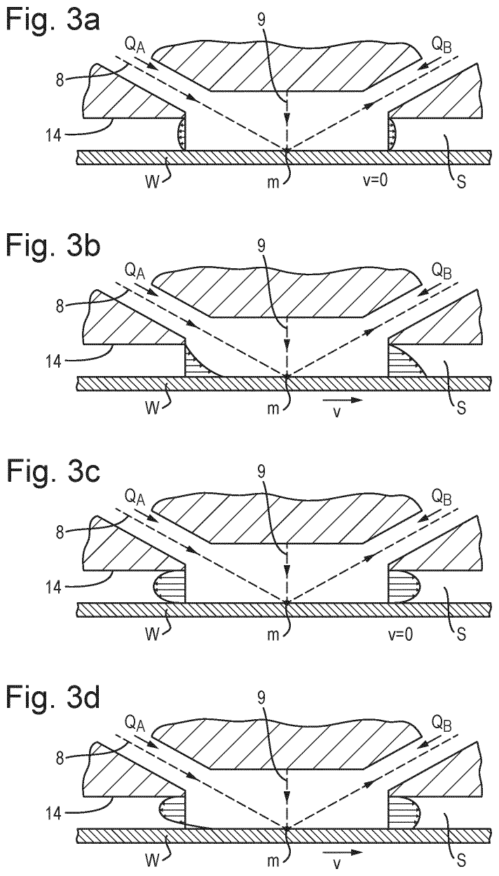

The effect of the flow rate of conditioning fluid F can be understood in more detail with reference to FIGS. 3a-3d. FIG. 3a depicts a scenario in which the substrate W is stationary (or quasi-static) with respect to the measurement device. A low flow of conditioning fluid F is used, resulting in low flow velocities in slit S. Applying the no-slip condition (whereby a viscous fluid at a solid boundary is treated as having negligible or zero velocity relative to the solid boundary), the flow velocity at the fluid flow control surface 14 and the flow velocity at the surface of the substrate W are zero. FIG. 3b depicts a scenario in which the low flow is maintained, but the substrate W is moving at speed v (to the right, as shown) relative to the measurement device. Taking the frame of reference of the measurement device, applying the no-slip condition, the flow velocity at the fluid flow control surface 14 is zero, and the flow velocity at the surface of the substrate W is v. As can be seen, a backflow of ambient fluid is created on the left side of the measurement location m. The backflow is reduced somewhat by the low flow of conditioning fluid F, but the entire flow profile is still in the backflow direction. This brings a large amount of ambient fluid from outside the slit S into the vicinity of the measurement location m.

FIG. 3c depicts a scenario in which the substrate W is stationary (or quasi-static) with respect to the measurement device. A high flow of conditioning fluid F is used, resulting in high flow velocities in slit S. The flow velocities at the fluid flow control surface 14 and at the surface of the substrate W are still zero due to the no-slip condition. FIG. 3d depicts a scenario in which the high flow is maintained, but the substrate W is moving at speed v (to the right, as shown) relative to the measurement device. As with the scenario shown in FIG. 3b, taking the frame of reference of the measurement device and applying the no-slip condition, the flow velocity at the fluid flow control surface 14 is zero, and the flow velocity at the surface of the substrate W is v. However, unlike in FIG. 3b, the backflow of ambient fluid is effectively suppressed by the high flow of conditioning fluid F. Specifically, there remains only a thin layer of backflow close to the surface of the substrate W, with the majority of the fluid flow pointing away from the measurement location m. Therefore, the amount of ambient fluid drawn in towards the measurement location m is reduced. Instead, the main bulk of the fluid flow in the slit S is made up of conditioning fluid F, flowing outwards away from the measurement location m. Thus, the fluid conditions (e.g. refractive index) in the vicinity of the measurement location m are stable and repeatable, and the optical sensor 10, 11, 12 can be calibrated accordingly to yield reliable and precise measurements without sacrificing measurement speed.

The composition of the conditioning fluid F may be substantially the same as that of the ambient fluid. This may be desirable because, even with the application of a high flow of conditioning fluid F, a small amount of backflow of ambient fluid may still exist. Therefore, the fluid conditions (e.g. refractive index) in the vicinity of the measurement location m may be further stabilized by matching the conditioning fluid F closely to the ambient fluid. Of course, in addition to matching the composition, temperature may also be matched.

The ambient fluid may be a gas or air, which can be generally present in a mentioned substrate zone WZ of the apparatus. For example, such ambient fluid can include gas originating from one or more gas showers 30, which gas showers 30 can be configured to direct gas to certain other areas of the apparatus than to the area of the substrate measuring position WT(M). As an example, such one or more gas showers 30 can be provided to condition one or more interferometer beams IFB of a mentioned interferometer system IF (see FIGS. 1 and 2).

As noted above, the conditioning fluid F may be provided by a conditioning system 50 of the lithography apparatus. The conditioning fluid F may similarly be a gas or air. Specifically, the conditioning fluid F may be a controlled gas or a gas mixture, for example ultra clean air, preferably dry, or one or more inert gasses.

Also, the conditioning system can be configured to provide a thermally conditioned conditioning fluid F, particularly when the system is configured to thermally condition that fluid. As an example, the conditioning system can comprise a heating and/or cooling system (not shown) to heat and/or cool the conditioning fluid F, one or more temperature sensors to measure the temperature of the conditioning fluid F, and a control system to control a heating and/or cooling system to heat and/or cool conditioning fluid F to a desired and/or predetermined stable conditioning temperature. Also, the conditioning system can include one or more fluid lines 23, 24 (shown in FIG. 1) and fluid pumps to pump conditioning fluid F to desired locations and/or to remove or extract conditioning fluid F from such locations. A part of the fluid conditioning system which can include a mentioned heating and/or cooling system, control system, temperature sensor and pumps is schematically indicated by the conditioning system 50 in FIG. 1. To the skilled person, it will be clear how different parts of the conditioning system 50 can be configured and arranged.

The space filling and/or space enclosing body 4 may be constructed in various ways, and of various materials. For example, this body 4 can be a substantially solid body, structure, plate and/or element, or this body 4 can be an at least partly hollow body, structure, plate and/or element. Also, the space filling and/or space enclosing body 4 may have a substantially fluid tight, or sealed, outer surface, except where specifically indicated otherwise. In an embodiment, the space filling and/or space enclosing body 4 is mounted to the intermediate frame part 3 of the apparatus, which frame part separates an interior zone, for example the substrate zone WZ, from another interior zone of the apparatus, e.g., the projection system zone PZ. For example, the space filling and/or space enclosing body 4 can be integrally connected or fixed to the intermediate frame part 3 of the apparatus, or be made in one piece with the intermediate frame part 3. The space filling and/or space enclosing body 4 may be made of one or more metals, plastics, alloys and/or a combination of these or other materials.

In an embodiment, during use, the closest distance (see FIG. 2) between the fluid flow control surface 14 of the body 4 and the substrate surface, or the width R of the slit S between the fluid flow control surface 14 and the substrate surface, is less than about 10 mm. For example, the closest distance between the fluid flow control surface 14 and the substrate surface, or the slit width R, may be in the range of about 1 to 5 mm or about 1 to 2 mm. For example, the slit width R may be about 2.5 mm. Alternatively, the mentioned closest distance, or slit width R, may be smaller than about 2.5 mm or small than about 1 mm. More generally, it may be desirable to minimize slit width R, provided that potential collisions between the measurement device and the substrate W are avoided. This is because a smaller slit width R may allow perturbations from the ambient fluid to be excluded with a smaller flow rate Q₁, Q₂ of conditioning fluid. The slit S may have a constant width of R across a portion or the entirety of the fluid flow control surface 14. As noted above, the fluid flow control surface 14 may be substantially flat, and may comprise small surface features.

The space filling and/or space enclosing body 4 may house one or more of the mentioned optical sensors 10, 11, 12 and/or field generators of the measuring device, as is depicted in FIG. 2. Besides, for example, in the present embodiment, the space filling and/or space enclosing body 4 may comprise the one or more measuring beam passages 5 to transmit the at least one measuring beam 8 of the measuring device through at least part of that body 4, between the optical sensors 10, 11, 12 and the aperture 141 in the fluid flow control surface 14. To the skilled person it will be clear how the measuring beam passages 5 can be configured in view of a respective measuring beam 8.

A measuring beam passage 5 may be at least partially co-extensive with a fluid passage 40. For example, as shown in FIG. 2, the measuring beam passage 5 for optical sensor 10 may be partially co-extensive with the fluid passage 40 shown on the left. Similarly, the measuring beam passage 5 for optical sensor 11 may be partially co-extensive with the fluid passage 40 shown on the right.

In embodiments in which several fluid passages 40 are provided, the fluid passages 40 may all direct conditioning fluid F to the aperture 141 surrounding the measurement location m. Furthermore, each fluid passage 40 may be used to conduct a fraction of the total flow rate Q of conditioning fluid F. For example, the two fluid passages 40 shown in FIG. 2 may conduct a fluid flow at flow rates Q_{A} and Q_{B} respectively, where Q_{A} and Q_{B} add up to total flow rate Q. In embodiments, more than two fluid passages 40 may be provided, and each such fluid passage 40 may conduct a fraction of the total flow rate Q. Accordingly, references to the first flow rate Q₁ and second flow rate Q₂ herein refer to the total flow rates flowing through the aperture 141 during the respective measurement processes, irrespective of the number of fluid passages 40 provided. As used herein, unless otherwise indicated, the flow rates Q, Q₁, Q₂, Q_{A} and Q_{B} may be either volumetric flow rates (e.g. in litres per minute, measured at atmospheric pressure (1.01325 bara) and a temperature of 0° C.) or mass flow rates (e.g. in grams per minute).

Generally, where several fluid passages 40 are provided, it may be desirable to non-equal fractions of the total flow rate Q through the different fluid passages 40. That is, in the example shown in FIG. 2, Q_{A} and Q_{B} may be different (and add up to Q). This asymmetry may help prevent a stagnation point from forming at the location of measurement m. For example, Q_{A}:Q_{B} (or Q_{B}:Q_{A}) may follow a 30:70 split, a 35:65 split, a 40:60 split, or a 45:55 split.

The sieve 26 may be provided at a location so that the conditioning fluid F passes through the sieve 26 before entering the co-extensive portion of the measuring beam 8/fluid passage 40. For example, the sieve 26 may be provided directly at the location where the conditioning fluid F enters the co-extensive portion.

The sieve 26 can include a porous material, a suitable gas disperser, mono filament cloth or fabric, one or more sheets having gas apertures, or a different fluid distributor. In an embodiment of the invention, a thickness of the sieve 26 may be smaller than about 1 mm. For example, the thickness may be about 0.5 mm or smaller. Also, the sheet may be a metal sheet or an alloy sheet, for example stainless steel. In that case, relatively small fluid passages can be manufactured with high accuracy using laser drilling. Fluid passages 40 may also be manufactured using different techniques. Also, the sieve 26 may be made of plastic, of one or more different materials. Besides laser drilling, different manufacturing methods may be applied to provide the passages of the sieve 26, such as etching the passages, manufacturing the passages by electric discharge machining, and/or using different processes like deposition of metal on a mask. The sieve 26 can also be called a “micro sieve”. The sieve 26 may include one or more layers of one or more materials. The sieve 26 may be, or provide, a wall or wall part of the space filling and/or space enclosing body 4. The fluid passages of the sieve 26 may have various diameters or dimensions. A diameter or width of each of the passages may be, for example, smaller than about 0.2 mm. For example, the diameter or width may be smaller than about 0.1 mm. Good results are obtained when the diameter or width of each of the passages is about 0.08 mm, and the conditioning fluid F is a gas or gas mixture.

As explained above with reference to FIGS. 3a-3d, a certain flow rate of conditioning fluid F may be necessary to adequately counteract the perturbations from ambient fluid when the measuring device is moving relative to the substrate W, particular during fast movements.

For example, the second (i.e. the higher) flow rate Q₂ may be set such that an average fluid speed in the region of substantially constant slit width R is at least about 70%, such as 80%, 90%, 100%, 110%, 120%, 130% or 140%, or up to about 150% of the second (i.e. higher) speed v₂. As used herein, “average fluid speed” may refer to the (scalar) speed of the fluid averaged over the volume of space occupied by the region of substantially constant slit width R. Mathematically, the average fluid speed may be expressed as:

$$\text{?} \frac{udG}{G} ,$$

where G is the volume of space occupied by the region of substantially constant slit width R, and u is the local scalar fluid speed at different points in G.

For another example, the second (i.e. the higher) flow rate Q₂ may be set such that an average fluid speed in the region of substantially constant slit width R is at least about 2.2 m/s, such as 2.4, 2.6, 2.8, 3.0, 3.2, 3.5 or 4.0 m/s, or up to about 4.5 m/s. This range of speed may correspond to the second speed v₂ at which the measurement device moves relative to the substrate W.

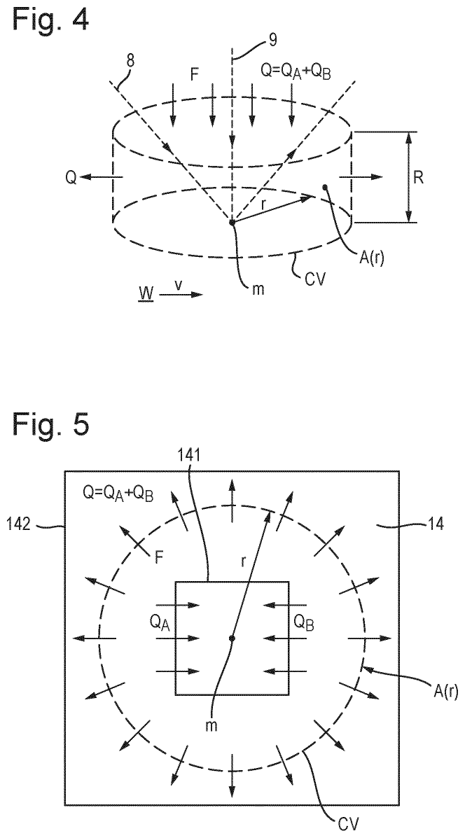

Reference is made to FIG. 4 for another definition of the flow rate Q. As shown, a control volume CV is defined by intersecting an (imaginary) cylinder and the slit S. If the fluid flow control surface 14 is flat and parallel to the surface of the substrate W, then the control volume CV takes the shape of a cylinder. Otherwise, the top surface of the control volume CV may follow the topography of the fluid flow control surface 14. The cylinder has a radius r, and has an axis of rotation perpendicular to the surface of the substrate W and passes through the location of measurement m. The radius r can be an arbitrary value as long as the cylindrical surface of the control volume CV is entirely encompassed within the region of substantially constant slit width R. At the smallest, the radius r may be just big enough for the control volume CV to encompass the aperture 141. At the largest, the radius r may be such that the control volume CV does not extend beyond the extent 142 of the region of constant slit width R. As shown in FIG. 5, the radius r may be a value somewhere in between the extremes. The surface area of the cylindrical surface is A(r), which is equal to 2πrR in case the fluid flow control surface 14 is flat and parallel to the surface of the substrate W.

As shown in FIGS. 4 and 5, a total flow rate Q of conditioning fluid F enters the control volume CV through the aperture 141. In the example shown, the total flow rate Q is made up of two fractions, Q_{A} and Q_{B}, entering through the two fluid passages 40 shown in FIG. 2. Therefore, the flow rate out of the control volume CV through the cylindrical surface equals the total flow rate Q in. Accordingly, assuming that the fluid density is constant, the average flow velocity out through the cylindrical surface is Q/A(r), where Q is a volumetric flow rate. This average flow velocity is at the highest when the radius r is at the smallest.

As shown in FIGS. 3b and 3d, the backflow velocity is at most v, which is the speed at which the substrate W moves relative to the measurement device. To adequately counteract the backflow, the average flow velocity out through the cylindrical surface, Q/A(r), may be set to be comparable to v. In other words, Q may be set so that the dimensionless parameter Q/(A(r)*v) is on the order of 1. For example, Q/(A(r)*v) may be at least about 0.7, such as about 0.8, 0.9, 1.0, 1.1, 1.2, 1.3 or 1.4, or up to about 1.5. Q/(A(r)*v) may be set to these values given that r is at the smallest (i.e. the control volume CV is just big enough to encompass the aperture 141).

As noted above, the second measurement process is performed at a higher speed v₂ than the first measurement process, and require a second flow rate Q₂ of conditioning fluid F higher than the first measurement process. Accordingly, the second flow rate Q₂ may be set according to v₂ using the approach above.

As an alternative, Q₂ may be set according to a desired range of average flow velocity out through the cylindrical surface, Q₂/A(r). For example, Q₂ may be set such that Q₂/A(r) is at least 2.2 m/s, such as 2.4, 2.6, 2.8, 3.0, 3.2, 3.5 or 4.5 m/s, or up to about 4.5 m/s. This range of speed may correspond to the second speed v₂ at which the measurement device moves relative to the substrate W.

After the substrate measuring process, the substrate W can be transferred to the substrate processing position WT(P), and the patterned beam of radiation PB, being patterned by a patterning device MA, can be projected onto the substrate W. Herein, the results of the detection of at least one aspect, characteristic, position and/or orientation of the substrate W can be used to accurately project the patterned beam of radiation PB onto the substrate W.

Also, in a further embodiment, the results of the detection of at least one aspect, characteristic, position and/or orientation of the substrate W can be used to align the substrate W with respect to a projection system PS, to project the patterned beam of radiation PB onto the substrate W. Besides, in a further embodiment, the results of the detection or measurement of the position and/or orientation of the substrate W can be used to align the substrate W with respect to a mentioned mask support MT constructed to support a patterning device MA, or with respect to the patterning device MA.

In this way, measuring errors of the measuring system can be reduced, and devices can be made with high precision. As is mentioned above, in a further embodiment, the substrate W does not have to be repositioned with respect to the substrate support WT during the period which runs from the measuring system measuring or detecting the substrate's position/orientation to the projection system PS having projected the radiation beam PB onto the substrate W.

Although the above disclosure refers to providing a conditioning fluid F in the slit S between the fluid flow control surface 14 and the surface of the substrate W, the present invention may be alternatively or additionally applied elsewhere. For example, as mentioned above, an encoder (not shown) may be used to implement a position measurement system PMS for determining the position of the substrate support WT, e.g. during the aforementioned first and second measurement processes during which optical sensor 10, 11, 12 measures the surface of the substrate W. Therefore, the encoder head may also move at first and second speeds v₁, v₂ relative to the grating of the encoder. Similar to the measurement device, the trade-off between excluding the perturbation from the ambient fluid and avoiding the generation of turbulence within internal passages may also apply to the encoder. Accordingly, the encoder head may also be supplied with a conditioning fluid at different flow rates corresponding to the processes performed at the first and second speeds v₁, v₂, so as to control the flow conditions in the space between the encoder head and the grating. That is, for slow or quasi-static movements, a low flow rate of conditioning fluid may be supplied. Conversely, for fast movements, a high flow rate of conditioning fluid may be supplied.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Aspects of the invention are described in the following numbered clauses:

1. A measurement device for measuring a substrate (W) in a lithographic apparatus, the measurement device comprising:
an optical sensor (10, 11, 12) configured to make a measurement of a surface of the substrate (W) by emitting a light beam (8, 9); and
a fluid supply configured to supply a conditioning fluid (F) traversing the light beam and flowing in a slit(S) between the measurement device and the surface of the substrate;
wherein the optical sensor is configured to perform a first measurement process while the measurement device is moving relative to the substrate at a first speed (v₁), and to perform a second measurement process while the measurement device is moving relative to the substrate at a second speed (v₂) higher than the first speed;
wherein the fluid supply is configured to supply the conditioning fluid at a first flow rate (Q1) during the first measurement process, and to supply the conditioning fluid at a second flow rate (Q2) higher than the first flow rate during the second measurement process.
   2. The measurement device of clause 1, wherein the optical sensor (12) comprises an alignment sensor configured to detect a marker on the surface of the substrate.
   3. The measurement device of clause 2, wherein the alignment sensor is configured to emit the light beam substantially perpendicular to the surface of the substrate.
   4. The measurement device of any one of the preceding clauses, wherein the optical sensor (10, 11) comprises a level sensor configured to measure a topography of the surface of the substrate.
   5. The measurement device of clause 4, wherein the level sensor is configured to emit the light beam at an angle of incidence of more than 45 degrees from the normal to the surface of the substrate, desirably between 70 degrees and 80 degrees.
   6. The measurement device of any one of the preceding clauses, comprising a plurality of optical sensors configured to emit respective light beams toward substantially the same location (m) on the surface of the substrate.
   7. The measurement device of any one of the preceding clauses, wherein the conditioning fluid is a gas.
   8. The measurement device of clause 7, wherein the conditioning fluid comprises gas or air, desirably ultra clean dry air or one or more inert gasses.
   9. The measurement device of clause 8, wherein the fluid supply is configured to supply air having substantially the same composition as ambient air as the conditioning fluid.
   10. The measurement device of any one of the preceding clauses, wherein the slit between the measurement device and the surface of the substrate comprises a region of substantially constant slit width (R).
   11. The measurement device of clause 10, wherein the second flow rate (Q₂) is set such that an average fluid speed in the region of substantially constant slit width is around 70% to 150% of the second speed (v₂).
   12. The measurement device of clause 10 or 11, wherein the second flow rate is set such that an average fluid speed in the region of substantially constant slit width is between 2.2 m/s and 4.5 m/s.
   13. The measurement device of clause 10, wherein the second flow rate is set to the following range:

0.7≤Q₂/(A(r)*v₂)≤1.5, where:
Q₂ is the second flow rate, being a volumetric flow rate,
v₂ is the second speed,
A(r) is the area of the cylindrical surface of the portion of an imaginary cylinder (CV) of radius r intersecting the slit, wherein the axis of rotation of the imaginary cylinder is perpendicular to the surface of the substrate and passes through the location (m) where the light beam is incident on the substrate (W), and r is a value such that the area A(r) is entirely encompassed within the region of substantially constant slit width.
   14. The measurement device of clause 10, wherein Q₂/A(r) is between 2.2 m/s and 4.5 m/s, where:
Q₂ is the second flow rate, being a volumetric flow rate,
A(r) is the area of the cylindrical surface of the portion of an imaginary cylinder (CV) of radius r intersecting the slit, wherein the axis of rotation of the imaginary cylinder is perpendicular to the surface of the substrate and passes through the location (m) where the light beam is incident on the substrate (W), and r is a value such that the area A(r) is entirely encompassed within the region of substantially constant slit width.
   15. A lithographic apparatus comprising the measurement device of any one of the preceding clauses.
   16. A method of measuring a substrate in a lithographic apparatus using a measurement device, the method comprising:
emitting a light beam (8, 9) onto a surface of the substrate (W); and
supplying a conditioning fluid (F) traversing the light beam and flowing in a slit(S) adjacent the surface of the substrate;
during a first measurement process, moving the substrate relative to the light beam at a first speed (v₁) supplying the conditioning fluid at a first flow rate (Q₁); and
during a second measurement process, moving the substrate relative to the light beam at a second speed (v₂) higher than the first speed while supplying the conditioning fluid at a second flow rate (Q₂) higher than the first flow rate.
   17. The method of clause 16, wherein the first measurement process comprises measuring a position of an alignment marker on the substrate.
   18. The method of clause 16 or 17, wherein the second measurement process comprises measuring a topography of the surface of the substrate.
   19. The method of any one of clauses 16 to 18, wherein the first measurement process and the second measurement process measure the substrate at substantially the same location (m).
   20. The method of any one of clauses 16 to 19, wherein the conditioning fluid is a gas.
   21. The method of clause 20, wherein the conditioning fluid comprises air, desirably extremely clean dry air or one or more inert gasses.
   22. The method of clause 21, wherein the conditioning fluid has substantially the same composition as ambient air.
   23. The method of any one of clauses 18 to 22, wherein the slit comprises a region of substantially constant slit width (R).
   24. The method of clause 22, wherein the second flow rate (Q₂) is set so that an average fluid speed in the region of substantially constant slit width is around 70% to 150% of the second speed (v₂).
   25. The method of clause 23, wherein the second flow rate is set so that an average fluid speed in the region of substantially constant slit width is between 2.2 m/s and 4.5 m/s.
   26. The method of clause 23, wherein the second flow rate is set to the following range:

0.7≤Q₂/(A(r)*v₂)≤1.5, where:
Q₂ is the second flow rate, being a volumetric flow rate,
v₂ is the second speed,
A(r) is the area of the cylindrical surface of the portion of an imaginary cylinder (CV) of radius r intersecting the slit, wherein the axis of rotation of the imaginary cylinder is perpendicular to the surface of the substrate and passes through the location (m) where the light beam is incident on the substrate (W), and r is a value such that the area A(r) is entirely encompassed within the region of substantially constant slit width.
   27. The method of clause 23, wherein Q₂/A(r) is between 2.2 m/s and 4.5 m/s, where:
Q₂ is the second flow rate, being a volumetric flow rate,
A(r) is the area of the cylindrical surface of the portion of an imaginary cylinder (CV) of radius r intersecting the slit, wherein the axis of rotation of the imaginary cylinder is perpendicular to the surface of the substrate and passes through the location (m) where the light beam is incident on the substrate (W), and r is a value such that the area A(r) is entirely encompassed within the region of substantially constant slit width.
   28. A method of manufacturing devices comprising the method of any one of clauses 16 to 27.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A measurement device for measuring a substrate in a lithographic apparatus, the measurement device comprising:
an optical sensor configured to make a measurement of a surface of the substrate by emitting a radiation beam; and
a fluid supply configured to supply a conditioning fluid traversing the beam and flowing in a slit between the measurement device and the surface of the substrate,
wherein the optical sensor is configured to perform a first measurement process while relative movement is provided between the measurement device and the substrate at a first speed, and to perform a second measurement process while relative movement is provided between the measurement device and the substrate at a second speed higher than the first speed, and
wherein the fluid supply is configured to supply the conditioning fluid at a first flow rate during the first measurement process, and to supply the conditioning fluid at a second flow rate higher than the first flow rate during the second measurement process.

2. The measurement device of claim 1, wherein the optical sensor comprises an alignment sensor configured to detect a marker on the surface of the substrate.

3. The measurement device of claim 1, wherein the optical sensor comprises a level sensor configured to measure a topography of the surface of the substrate.

4. The measurement device of claim 3, wherein the level sensor is configured to emit the beam at an angle of incidence of more than 45 degrees from the normal to the surface of the substrate.

5. The measurement device of claim 1, wherein the slit between the measurement device and the surface of the substrate comprises a region of substantially constant slit width.

6. The measurement device of claim 5, wherein 0.7≤Q₂/(A(r)*v₂)≤1.5, where:
Q₂ is the second flow rate, being a volumetric flow rate,
v₂ is the second speed,
A(r) is the area of the cylindrical surface of the portion of an imaginary cylinder of radius r intersecting the slit, wherein the axis of rotation of the imaginary cylinder is perpendicular to the surface of the substrate and passes through the location where the beam is incident on the substrate, and r is a value such that the area A(r) is entirely encompassed within the region of substantially constant slit width, or
wherein Q₂/A(r) is between 2.2 m/s and 4.5 m/s, where:
Q₂ is the second flow rate, being a volumetric flow rate,
A(r) is the area of the cylindrical surface of the portion of an imaginary cylinder of radius r intersecting the slit, wherein the axis of rotation of the imaginary cylinder is perpendicular to the surface of the substrate and passes through the location where the beam is incident on the substrate, and r is a value such that the area A(r) is entirely encompassed within the region of substantially constant slit width.

7. A lithographic apparatus comprising the measurement device of claim 1.

8. A method of measuring a substrate in a lithographic apparatus using a measurement device, the method comprising:
emitting a radiation beam onto a surface of the substrate;
supplying a conditioning fluid traversing the beam and flowing in a slit adjacent the surface of the substrate;
during a first measurement process, providing relative movement between the substrate and the beam at a first speed while supplying the conditioning fluid at a first flow rate; and
during a second measurement process, providing relative movement between the substrate and the beam at a second speed higher than the first speed while supplying the conditioning fluid at a second flow rate higher than the first flow rate.

9. The method of claim 8, wherein the first measurement process comprises measuring a position of an alignment marker on the substrate, and/or wherein the second measurement process comprises measuring a topography of the surface of the substrate, and/or wherein the first measurement process and the second measurement process measure the substrate at substantially the same location.

10. The method of claim 8, wherein the conditioning fluid comprises air.

11. The method of claim 8, wherein the slit comprises a region of substantially constant slit width.

12. The method of claim 11, wherein the second flow rate is set so that an average fluid speed in the region of substantially constant slit width is around 70% to 150% of the second speed or wherein the second flow rate is set so that an average fluid speed in the region of substantially constant slit width is between 2.2 m/s and 4.5 m/s.

13. The method of claim 11, wherein 0.7≤Q₂/(A(r)*v₂)≤1.5, where:
Q₂ is the second flow rate, being a volumetric flow rate,
v₂ is the second speed,
A(r) is the area of the cylindrical surface of the portion of an imaginary cylinder of radius r intersecting the slit, wherein the axis of rotation of the imaginary cylinder is perpendicular to the surface of the substrate and passes through the location where the beam is incident on the substrate, and r is a value such that the area A(r) is entirely encompassed within the region of substantially constant slit width.

14. The method of claim 11, wherein Q₂/A(r) is between 2.2 m/s and 4.5 m/s, where:
Q₂ is the second flow rate, being a volumetric flow rate,
A(r) is the area of the cylindrical surface of the portion of an imaginary cylinder of radius r intersecting the slit, wherein the axis of rotation of the imaginary cylinder is perpendicular to the surface of the substrate and passes through the location where the beam is incident on the substrate, and r is a value such that the area A(r) is entirely encompassed within the region of substantially constant slit width.

15. A method of manufacturing devices comprising the method of any of claim 8.

16. The method of claim 8, wherein the conditioning fluid is a gas.

17. The measurement device of claim 1, wherein the conditioning fluid is a gas.

18. The measurement device of claim 1, comprising a plurality of optical sensors configured to emit respective radiation beams toward substantially the same location on the surface of the substrate.

19. The measurement device of claim 5, wherein the second flow rate is set such that an average fluid speed in the region of substantially constant slit width is around 70% to 150% of the second speed.

20. The measurement device of claim 5, wherein the second flow rate is set such that an average fluid speed in the region of substantially constant slit width is between 2.2 m/s and 4.5 m/s.
